(19) United States
(12) Patent Application Publication
(10) Pub. No.: US 2016/0170117 A1
(43) Pub. Date: Jun. 16, 2016

(54) LIGHT EMITTING MODULE AND METHOD FOR GENERATING ULTRABROADBAND NEAR-INFRARED LIGHT

(71) Applicant: National Taiwan University of Science and Technology, Taipei (TW)

(72) Inventors: Ping-hui Yeh, Taipei (TW); Heng-i Lee, Taipei (TW)

(73) Assignee: National Taiwan University of Science and Technology, Taipei (TW)

(21) Appl. No.: 14/798,655

(22) Filed: Jul. 14, 2015

(30) Foreign Application Priority Data
Dec. 15, 2014 (TW) 103143625

(51) Int. Cl. G02B 5/30; H01S 5/022; G02B 26/00; G02B 6/42

(52) U.S. Cl. CPC G02B 5/3083; G02B 6/4206; H01S 5/02284; G02B 26/007

(57) ABSTRACT

The present invention discloses a light emitting module and a method for generating ultrabroadband near-infrared light and increasing the bandwidth and output power. The light emitting module includes a linearly polarized laser pump for generating a visible laser, a half-wave plate for adjusting the to polarization orientation of the visible laser, and a crystal optical fiber disposed on the output light path of the half-wave plate. The core of the crystal optical fiber is made of forsterite (Mg₂SiO₄) doped with Cr³⁺ and Cr⁴⁺ ions. The doping process comprises: depositing a chromium oxide layer on the lateral surface of the core and driving the chromium atoms into the core by high temperature diffusion; coupling the visible laser into the core to produce a spontaneous emission with wavelengths from 750 to 1350 nm continuously. Particularly, the continuous spectrum is adjustable by changing the polarization orientation of the visible laser via the half-wave plate.

### BACKGROUND OF THE INVENTION

(1) Field of the Invention

The present invention relates to an ultrabroadband light source, particularly for one that employs solid gain medium to contrive a light emitting module and method for generating ultrabroadband near-infrared light.

(2) Description of the Prior Art

The traditional near-infrared (NIR) light sources include ytterbium-doped fiber (Yb: fiber) lasers, laser diodes and light emitting diodes (LED), whose full width at half maximum (FWHM), namely 3-db bandwidth, are not over 30 nm. The conventional broadband NIR light sources with FWHM larger than 50 nm can be classified into five categories: superluminescent diode (SLD), broadband LED, supercontinuum light source, fiber-based amplified spontaneous emission (ASE), and bulk-crystal-based ASE.

The ultrabroadband characteristic of SLD or LED is generated by having multiple quantum wells of various bandgaps epitaxially grown on semiconductor substrate. However, these devices require complicated wafer growth and only operate at specific working current. In another word, their spectral bandwidths change with the operating current and the optical power level.

The ultrabroadband characteristic of the supercontinuum light source is generated by a dispersive erbium doped fiber amplifier pumped by a high-peak-power pulse laser, and the bandwidth thereof is broadened by self phase modulation of Kerr effect and other nonlinear effects so that the bandwidth thereof is in range of 1420-1700 nm. However, the supercontinuum light source is not suitable for many commercial applications owing to complicated scheme, non-continuous wave operation and high-price of system facility.

The ultrabroadband fiber-based ASE is generated by a rare-earth-ion doped fiber or a chromium doped fiber amplifier (CDFA).

Wherein, the operating principle of the rare-earth-ion doped fiber is that each dopant of rare-earth-elements such as erbium (Er), neodymium (Nd) and ytterbium (Yb) is doped into optical fiber and the output light source thereof is coupled into the optical fiber. Upon the rare-earth-ion doped fiber absorbs the energy of the pumping light, some electrons in the ground state are transited to the metastable state so that the population inversion of the system is reached. When the signal of incident light with frequency band in corresponding with the spontaneous emission section of the rare-earth-ion doped fiber medium passes the rare-earth-ion doped fiber, some electrons in the metastable state are stimulated back to the ground state and emit light waves of wavelengths depending on the dopant's energy band structure.

The operating principle of the chromium doped fiber amplifier (CDFA) is the same as that of the rare-earth-ion doped fiber except the host material is a crystal fiber instead of a glass fiber. Currently, chromium-doped Yttrium Aluminum Garnet (Cr: YAG) and Cr⁴⁺: forsterite have been made as chromium doped fiber amplifier (CDFA) to have broadband radiation spectra of wavelength ranges of 1250-1650 nm and 1050-1350 nm, respectively, which cannot be provided by the conventional optical fibers and semiconductor light sources.

The bulk-crystal-based ASE is generated by an active-ion doped bulk crystal, e.g. Ti: sapphire, Cr: YAG and Cr⁴⁺: forsterite. However, not only the size thereof is bulky but also the price thereof is expensive.

In conclusion the disclosure heretofore, how to increase the output power and provide broader bandwidth for the near-infrared (NIR) light source becomes an urgent and critical issue.

### SUMMARY OF THE INVENTION

The primary object of the present invention is to provide a light emitting module of near-infrared light, which can substantially enhance the bandwidth and optical output power thereof.

The other object of the present invention is to provide a new ultrabroadband light generation method by combining emissions from two types of active ions and employing a new pumping wavelength shorter than previously used. The fabrication method of the new optical fiber material doped with two types of active ions to substantially enhance the bandwidth and optical output power of near-infrared light is described.

In order to achieve partial or all objects aforesaid, the present invention provides a light emitting module of ultrabroadband near-infrared light comprising a primal pump light source, a half-wave plate and a crystal optical fiber. The primal pump light source is adapted to generate a linearly polarized visible laser, for example, a diode laser or a laser with polarizer. The half-wave plate is disposed in an output light path of the linearly polarized visible laser, to regulate a polarization orientation of said visible laser. The crystal optical fiber is disposed in the output light path of the half-wave plate. The crystal optical fiber comprises a core made of forsterite crystal doped with trivalent chromium ions (Cr³⁺) and tetravalent chromium ions (Cr⁴⁺). It is worth noting that a chromium doping process is performed as that a chromium oxide layer (Cr₂O₃) is deposited on a lateral surface of the core, and the chromium ions are driven into the core by high temperature diffusion. The trivalent chromium ions (Cr³⁺) and tetravalent chromium ions (Cr⁴⁺) in the core are suitably stimulated by said visible laser to generate an amplified spontaneous emission having a combinational overlapping continuous spectrum with wavelength in range from 750 to 1350 nm. The spectral intensity distribution and the full width at half maximum (FWHM) of said continuous spectrum is adjustable by changing the polarization orientation of the visible laser via the half-wave plate.

In an embodiment, the light emitting module of ultrabroadband near-infrared light further comprises a first aspheric lens, a second aspheric lens and a long-wave pass filter. The first aspheric lens is disposed between the primal pump light source and the half-wave plate to collimate the visible laser. The second aspheric lens is disposed between the half-wave plate and the crystal optical fiber to focus the visible laser into the fiber. The long-wave pass filter is disposed at the output end of the crystal optical fiber to remove any residual laser pump power.

In an embodiment, the core of the crystal optical fiber has a diameter in range of 5 to 200 μm. The full width at half maximum (FWHM) of the continuous spectrum generated by the crystal optical fiber is in range of 150 to 300 nm.

In another aspect, the present invention provides a method for generating ultrabroadband near-infrared light, comprising steps of: preparing a core by material of forsterite crystal doped with tetravalent chromium ions (Cr⁴⁺); performing a lateral-plating process on the lateral surface of the core to deposit a chromium oxide layer (Cr₂O₃); performing a high temperature heating process to diffuse trivalent chromium ions (Cr³⁺) into the core so that a Cr³⁺ and Cr⁴⁺ co-doped crystal optical fiber is produced by the core; providing a linearly polarized visible-light laser pump and a half-wave plate, wherein an visible laser generated from the visible-light laser pump and traveling through the half-wave plate is coupled into the crystal optical fiber for stimulating the trivalent chromium ions (Cr³⁺) to generate a first spontaneous emission and stimulating the tetravalent chromium ions (Cr⁴⁺) to generate a second spontaneous emission; and regulating the polarization orientation of the visible laser by rotating the half-wave plate, so that the relative intensity ratio for the first spontaneous emission to the second spontaneous emission is adjusted accordingly until a continuous spectrum with wavelength in range from 750 to 1350 nm is created by a combinational overlapping effect of respective spectrum emitted by the first spontaneous emission and the second spontaneous emission in accordance with the superposition principle.

In an embodiment, the polarization orientation of the visible laser is regulated via adjusting the polarization orientation of the visible laser light to the extent that the relative intensity for the first spontaneous emission to the second spontaneous emission is in same numerical order, so that the continuous spectrum with the full width at half maximum (FWHM) not less than 220 nm is created.

In an embodiment, the method further comprises: before performing the lateral-plating process, performing a Laser heated pedestal growth (LHPG) technique for the core, to reduce an original diameter of the core down to range of 5 to 200 μm.

The present invention adopt new optical fiber material with improvement in the fabricating method of crystal optical fiber to substantially increase the concentration of chromium ions (Cr³⁺ and Cr⁴⁺) doped in the crystal optical fiber. Moreover, the visible-light laser pump is used to provide new frequency band of pumping light for obviously enhance the optical output power of the light emitting module of near-infrared light. Meanwhile, by adjusting the polarization orientation of the pumping light source, a new frequency band is created with widened bandwidth. Comparing to the conventional counterpart and technology, the present invention apparently has advantageous features in ultrabroadband, new frequency band and good penetrating depth for the human tissues.

### BRIEF DESCRIPTION OF THE DRAWINGS

FIG. 1 is a schematic view showing a light emitting module for generating ultrabroadband near-infrared light in an exemplary embodiment of the present invention.

FIG. 2 is a schematic view showing a core of crystal optical fiber with lateral plating of chromium oxide layer in the light emitting module of ultrabroadband near-infrared light for an exemplary embodiment of the present invention.

FIG. 3 is a cross sectional view showing a structure of crystal optical fiber in an exemplary embodiment of the present invention.

FIG. 4 is a schematic view showing a continuous emission spectrum for a light emitting module of ultrabroadband near-infrared light in an exemplary embodiment of the present invention.

### DESCRIPTION OF THE PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

The light emitting module for generating ultrabroadband near-infrared light of the present invention, which is a light source of amplified spontaneous emission, comprises a pump light source and a gain medium with two types of active ions. Wherein, some internal electrons in the gain medium are transited to higher energy level of excited state after having absorbed energy from the pump light source. If lifetime for the transited electron of the excited state ends, an original spontaneous emission will occur and stimulate other electrons in the excited state, to cause electromagnetic wave of same phase, and propagation direction as those of the original spontaneous emission, so that an amplified spontaneous emission is achieved.

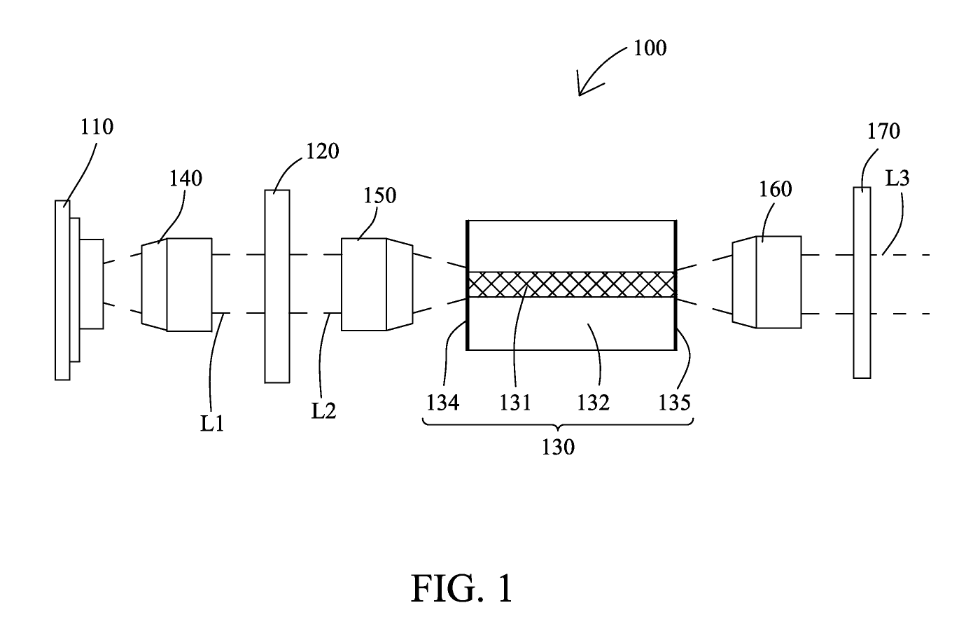

Please refer to FIG. 1, which shows a light emitting module of ultrabroadband near-infrared light 100 in an exemplary embodiment of the present invention. The light emitting module of ultrabroadband near-infrared light 100 comprises a primal pump light source 110, a half-wave plate 120, a crystal optical fiber 130. Wherein, the primal pump light source 110 is a linearly polarized visible-light laser pump such as a diode laser or a laser with polarizer, which is suitably adapted to generate a linearly polarized visible laser L1 with wavelength in range from 400 to 740 nm. Accordingly, a multi-mode red diode laser of 660-700 nm in wavelength is adopted as the primal pump light source 110 in an exemplary embodiment of the present invention. It is worth noting that the linearly polarized visible-light laser pump adopted as the primal pump light source 110 in the exemplary embodiment can boost up optical output power in the light emitting module of ultrabroadband near-infrared light 100.

The half-wave plate 120, which is disposed in the output light path of the visible laser L1, is used to regulate the polarization orientation of the visible laser L1 resulting in visible laser L2 with the adjusted polarization orientation to be coupled into the crystal optical fiber 130. The crystal optical fiber 130, which is disposed in the output light path of the half-wave plate 120 to serve as a gain medium, includes a core 131, a fiber cladding or clad 132, an input end 134 and an output end 135. The core 131 is made of forsterite crystal with dopant of trivalent chromium ions (Cr³⁺) and tetravalent chromium ions (Cr⁴⁺). And the clad 132 is made of glass of single layer or multiple layers to serve as sheath of the core 131.

It is worth noting that the lateral surface of the core 131 is lateral-plated with a layer of chromium oxide (Cr₂O₃) to increase the doping concentration of trivalent chromium ions (Cr³⁺) and to change the doping concentration ratio between the dopant of trivalent chromium ions (Cr³⁺) and dopant of tetravalent chromium ions (Cr⁴⁺). The original spontaneous emission and the amplified spontaneous emission occur in the crystal optical fiber 130 when the trivalent chromium ions (Cr³⁺) and tetravalent chromium ions (Cr⁴⁺) is stimulated by the visible laser L2 so that an output light through the output end 135 is obtained with continuous spectrum in wavelength range from 750 to 1350 nm. The intensity distribution and full width at half maximum (FWHM) for the continuous spectrum of the amplified spontaneous emissions can be adjusted by changing the polarization orientation of the visible laser.

In an exemplary embodiment, the light emitting module of ultrabroadband near-infrared light 100 aforesaid further comprises a first aspheric lens 140, a second aspheric lens 150, a third aspheric lens 160 and a long-wave pass filter 170. The first aspheric lens 140, which is disposed between the primal pump light source 110 and the half-wave plate 120, functions to collimate the output light from the primal pump light source 110 for directing into the first visible laser L1. The second aspheric lens 150, which is disposed between the half-wave plate 120 and crystal optical fiber 130, functions to focus the visible laser L2 into the input end 134 of the crystal optical fiber 130. The third aspheric lens 160, which is disposed between the crystal optical fiber 130 and the long-wave pass filter 170, functions to reduce divergent angle of the output light from the output end 135 of the crystal optical fiber 130. The visible laser L2 is not absorbed completely in the crystal optical fiber 130, so some residual visible laser L2 passes through the output end 135. Therefore, the long-wave pass filter 170 is disposed at the final stage of the light emitting module of ultrabroadband near-infrared light 100, functions to filter out the residual visible laser L2 so that a resultant light L3 is obtained.

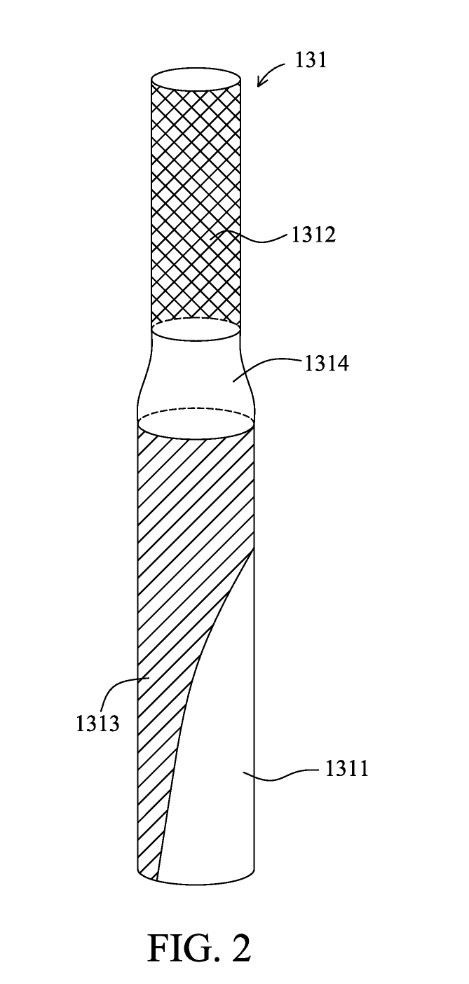

Please refer to FIG. 2, which shows the doping process of the core 131 of crystal optical fiber with lateral plating of chromium oxide layer (Cr₂O₃) 1313 in the light emitting module of ultrabroadband near-infrared light 100 for an exemplary embodiment of the present invention. The procedure is performed as follows: firstly, prepare a forsterite fiber 1311 laterally plated with a chromium oxide layer (Cr₂O₃) 1313; secondly, use Laser heated pedestal growth (LHPG) technique to heat the prepared fiber to diffuse the chromium in the Cr₂O₃ layer into the fiber 1311 which becomes a highly doped fiber 1312 after the heating zone 1314. It is worth noting that the core 131 has a diameter in range of 5 to 200 μm, so the highly doped fiber 1312 may be re-grown by LHPG again to reduce the fiber diameter.

The power of the amplified spontaneous emission (ASE) of the core 131 relates to the concentration of chromium ion and of defect that exist in the core 131. For fabricating the core 131, a Laser heated pedestal growth (LHPG) technique is employed in an exemplary embodiment to reduce original diameter of 500 μm for a seed crystal bar of forsterite into interim diameter of 290 μm via preliminary pull, then further reduce the interim diameter of 290 μm thereof into resultant diameter of 70 μm via post pull. It is worth noting that the concentration of chromium ion in the core 131 is decreased for each preliminary pull or post pull. In order to make up the decrease for the concentration of chromium ion in the core 131, some compensating methods are created to deposit a chromium oxide layer (Cr₂O₃) 1313 over the lateral surface of the seed crystal fiber 1311 to increase the concentration of chromium ion in the core 131. These compensating methods applied in exemplary embodiments of the present invention are all named as “lateral plating”.

Basic process of lateral plating is that disposing a chromium oxide target in a crucible, and utilizing electron beam to bombard the chromium oxide target for depositing and forming the chromium oxide layer (Cr₂O₃) 1313 on the lateral surface of the seed crystal fiber 1311 of forsterite denoted by “Cr:Forsterite”, so that trivalent chromium ions (Cr³⁺) are doped into the core 131. For the purpose of reducing pulling number of the highly doped fiber 1312 to retain the doing concentration, in an exemplary embodiment, the preliminary pull is performed on a seed crystal fiber 1311 to reduce original diameter into interim diameter of 140 μm before the lateral plating process, then the post pull is performed after the lateral plating process to further reduce the interim 140 μm diameter thereof into a desirable diameter, e.g. 40 μm. In another exemplary embodiment, the preliminary pull is performed on a seed crystal fiber 1311 to reduce original diameter into resultant diameter of 70 μm before the lateral plating process.

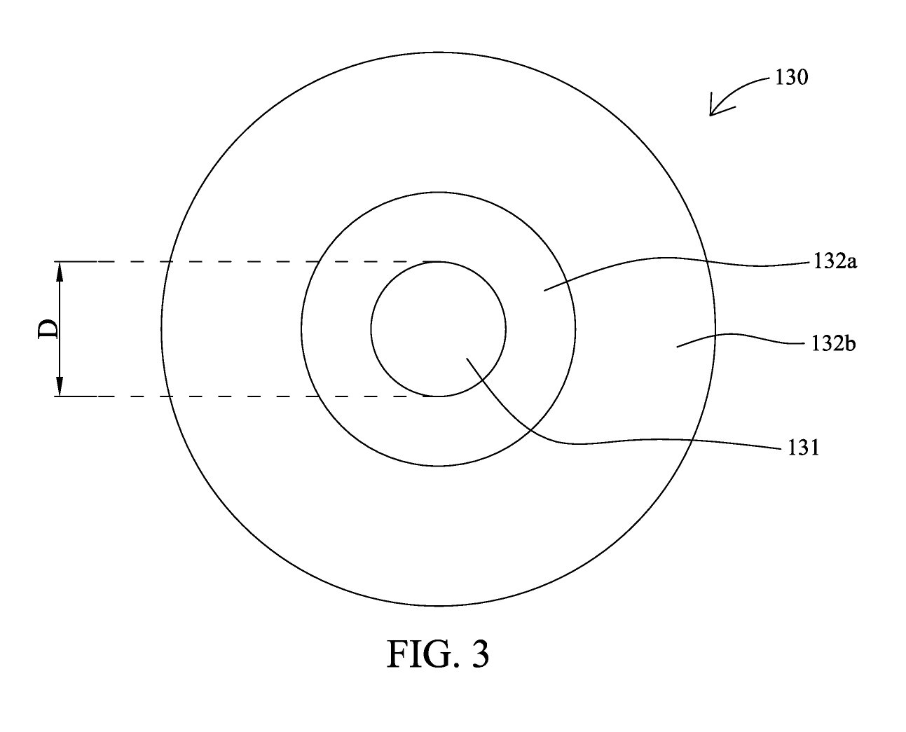

Please refer to FIG. 3, which shows a structure of crystal optical fiber in an exemplary embodiment of the present invention. In order to enhance the optical waveguide feature and reduce the transmission loss for the crystal optical fiber 130 of forsterite crystal (Cr:Forsterite) with dopant of trivalent chromium ions (Cr³⁺) or tetravalent chromium ions (Cr⁴⁺), the fiber cladding or clad 132 of glass with capillaries is selected in lower refractive index to serve as sheath of the core 131. In an exemplary embodiment, the fiber cladding or clad 132 is made of two different materials to be configured into a double-clad crystal fiber (DCF) 130. An inner cladding 132a is made of glass capillaries of aluminosilicate with refractive index of 1.538, whose inner and outer diameters are 75 μm and 120 μm respectively. An outer cladding 132b is made of glass capillaries of borosilicate with refractive index of 1.474, whose inner and outer diameters are 150 μm and 250 μm respectively.

In order to effectively dope the trivalent chromium ions (Cr³⁺) into the core 131, laser heated diffusion process or annealing process can be adopted. In laser heated diffusion process, the dopants of the trivalent chromium ions (Cr³⁺) are driven and diffused into the core 131 by laser heating on the chromium oxide layer (Cr₂O₃) 1313. In annealing process, the concentration of the trivalent chromium ions (Cr³⁺) can be promoted or the concentration ratio for the trivalent chromium ions (Cr³⁺) to the tetravalent chromium ions (Cr⁴⁺) can be adjusted via annealing on the chromium oxide layer (Cr₂O₃) 1313.

Heat dissipation is a critical issue for crystal-based light sources because the pump light source injects high power and crystal material usually has low thermal conductivity. In order to improve the heat dissipation in the crystal optical fiber 130, metal with good heat conduction can be used as coating material to achieve improvement of heat dissipation normally. Currently, there are two prevalent coating methods that metal coating method and hot melt adhesive-silver plastic coating method. In ordinary glass optical fiber, a neat end can be directly cleaved with a precision cleaver. However, in crystal optical fiber 130 of the present invention, after having finished heat-dissipation coating process and cleaving process, the crystal optical fiber 130 needs further special grinding process and polishing process to obtain expected neat end.

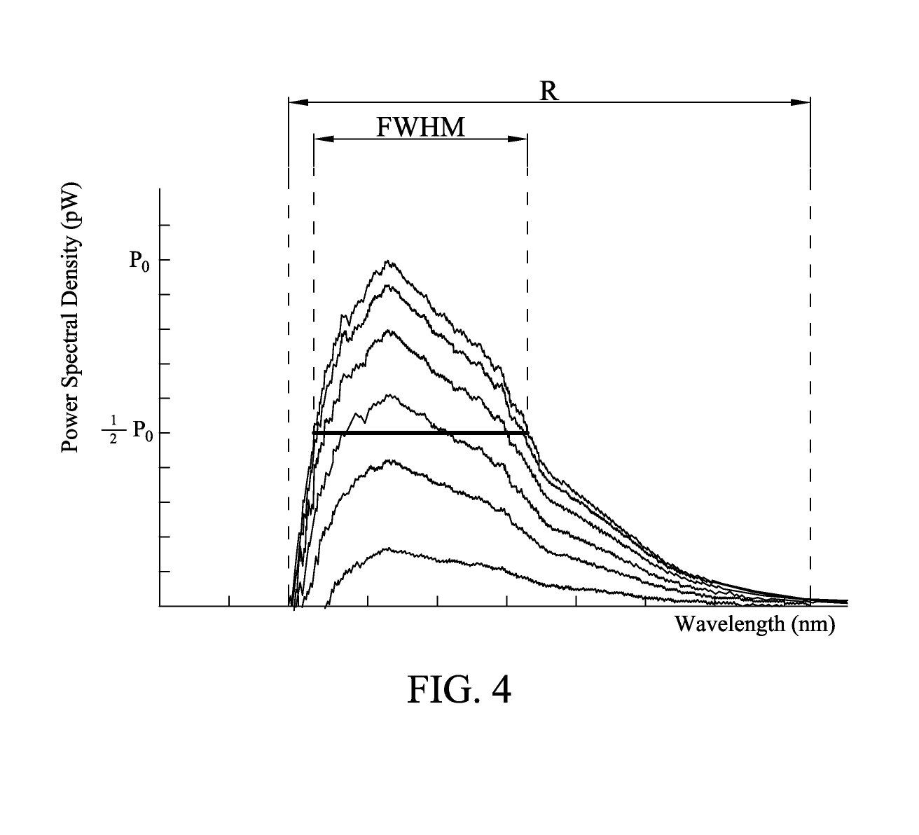

Please refer to FIG. 4, which shows a continuous spectrum for a light emitting module of ultrabroadband near-infrared light in an exemplary embodiment of the present invention, wherein vertical axis denotes to power spectral density (PSD) for spectral intensity while horizontal axis denotes to wavelength. The continuous spectrum emitted by the crystal optical fiber 130 is a combinational overlapping effect of respective spectrum emitted by the trivalent chromium ions (Cr³⁺) and respective spectrum emitted by the tetravalent chromium ions (Cr⁴⁺) in accordance with the superposition principle. The intensity distribution of the combinational continuous spectrum emitted by the crystal optical fiber 130 can be changed via adjusting polarization orientation of the visible laser so that the full width at half maximum (FWHM) is increased too. For example, in an exemplary embodiment, the wavelength scope (R) for the continuous spectrum emitted by the crystal optical fiber 130 is increased from range of 1100-1350 nm to range of 750-1350 nm while the adjustable scope for the full width at half maximum (FWHM) is increased to range of 150-300 nm too.

In summary of the disclosure heretofore, the method for generating ultrabroadband near-infrared light of the present invention covers following steps.

Firstly, prepare a core 131 by material of forsterite crystal (Cr:Forsterite) 1311 with dopant of tetravalent chromium ions (Cr⁴⁺). Secondly, perform a lateral-plating process on the lateral surface of the core 131 to deposit a chromium oxide layer (Cr₂O₃) 1313. And finally, via high temperature heating process, diffuse the dopants of the trivalent chromium ions (Cr³⁺) into the core 131 so that a crystal optical fiber 130 is produced by the core 131.

Henceforth, a visible-light laser pump 110 and a half-wave plate 120 are provided. The linearly polarized visible laser L1 generated from the visible-light laser pump 110 and traveling through the half-wave plate 120 is coupled into the crystal optical fiber 130 for simultaneously stimulating the trivalent chromium ions (Cr³⁺) to generate a first spontaneous emission and stimulating the tetravalent chromium ions (Cr⁴⁺) to generate a second spontaneous emission. In an exemplary embodiment, the first spontaneous emission generated by the trivalent chromium ions (Cr³⁺) can be used as pumping light source for the second spontaneous emission of tetravalent chromium ions (Cr⁴⁺).

Then the half-wave plate 120, which is disposed in the output light path of the visible laser L1, functions for regulating the polarization orientation of the visible laser L1 to form a visible laser L2, so that the relative intensity ratio for the first spontaneous emission to the second spontaneous emission can be adjusted accordingly until a continuous spectrum with wavelength in range from 750 to 1350 nm is created by a combinational overlapping effect of respective spectrum emitted by the first spontaneous emission and the second spontaneous emission in accordance with the superposition principle.

It is worth noting that the polarization orientation of the visible laser L2 will affect the combinational overlapping continuous spectrum in the present invention. For example, via adjusting the polarization orientation of the visible laser L2 to the extent that the relative intensity for the first spontaneous emission to second spontaneous emission is in same numerical order, a combinational overlapping continuous spectrum with a full width at half maximum (FWHM) of not less than 220 nm is created.

Moreover, it is also worth noting that the timing arrangement for the lateral plating process is critical for the resultant core 131 in the present invention. For example, the preliminary pull with the Laser heated pedestal growth (LHPG) technique is performed on a seed crystal bar to reduce original diameter into an interim or resultant diameter less than 200 μm, such as 140 μm, 70 μm or 40 μm for a seed crystal fiber 1311, before the lateral plating process.

The present invention adopt new optical fiber material with improvement in the fabricating method of crystal optical fiber to substantially increase the concentration of chromium ions (Cr³⁺ and Cr⁴⁺) doped in the crystal optical fiber. Moreover, the visible-light laser pump is used to provide new frequency band of pumping light for obviously enhance the optical output power of the light emitting module of near-infrared light. Meanwhile, by adjusting the polarization orientation of the pumping light source, a new frequency band is created with widened bandwidth. Comparing to the conventional counterpart and technology, the present invention apparently has advantageous features in ultrabroadband, new frequency band and good penetrating depth for the human tissues. Other than these advantageous features, the practical light emitting module of the present invention is also suitably used as light source of optical coherence tomography (OCT) and applied in related products of lasers with tunable wavelength, broadband light source in near-infrared (NIR) and ultrafast laser because of vantage thereof in compact size with competitive price.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light emitting module of ultrabroadband near-infrared light comprising:
a primal pump light source, adapted to generate a linearly polarized visible laser;
a half-wave plate, disposed in an output light path of the linearly polarized visible laser, to regulate a polarization orientation of said visible laser; and
a crystal optical fiber, disposed in an output light path of the half-wave plate, comprising a core made of forsterite crystal doped with trivalent chromium ions (Cr³⁺) and tetravalent chromium ions (Cr⁴⁺) such that a chromium doping process is performed as that a chromium oxide layer (Cr₂O₃) is deposited on a lateral surface of the core, and the chromium ions are driven and deposited into the core by high temperature diffusion, wherein the trivalent chromium ions (Cr³⁺) and tetravalent chromium ions (Cr⁴⁺) in the core are suitably stimulated by said visible laser to generate an amplified spontaneous emission having a combinational overlapping continuous spectrum with wavelength in range from 750 to 1350 nm such that a spectral intensity distribution and a full width at half maximum (FWHM) of said continuous spectrum is adjustable by changing the polarization orientation of the visible laser via the half-wave plate.

2. The light emitting module of ultrabroadband near-infrared light as claimed in claim 1, wherein the core of the crystal optical fiber has a diameter in range of 5 to 200 μm.

3. The light emitting module of ultrabroadband near-infrared light as claimed in claim 1, wherein the full width at half maximum (FWHM) of the continuous spectrum generated by the crystal optical fiber is in range of 150 to 300 nm.

4. The light emitting module of ultrabroadband near-infrared light as claimed in claim 1, wherein the primal pump light source is selected from one of a diode laser and a laser with polarizer.

5. The light emitting module of ultrabroadband near-infrared light as claimed in claim 1, further comprising a first aspheric lens disposed between the primal pump light source and the half-wave plate to collimate the visible laser.

6. The light emitting module of ultrabroadband near-infrared light as claimed in claim 5, further comprising a second aspheric lens disposed between the half-wave plate and the crystal optical fiber to focus the visible laser into the crystal optical fiber.

7. The light emitting module of ultrabroadband near-infrared light as claimed in claim 6, further comprising a long-wave pass filter disposed at an output end of the crystal optical fiber.

8. A method for generating ultrabroadband near-infrared light, comprising steps of:
preparing a core by material of forsterite crystal doped with tetravalent chromium ions (Cr⁴⁺);
performing a lateral-plating process on a lateral surface of the core to deposit a chromium oxide layer (Cr₂O₃);
performing a high temperature heating process, to diffuse trivalent chromium ions (Cr³⁺) into the core so that a Cr³⁺ and Cr⁴⁺ co-doped crystal optical fiber is produced by the core;
providing a linearly polarized visible-light laser pump and a half-wave plate, wherein an visible laser generated from the visible-light laser pump and traveling through the half-wave plate is coupled into the crystal optical fiber for stimulating the trivalent chromium ions (Cr³⁺) to generate a first spontaneous emission and stimulating the tetravalent chromium ions (Cr⁴⁺) to generate a second spontaneous emission; and
regulating the polarization orientation of the visible laser by rotating the half-wave plate, so that a relative intensity ratio for the first spontaneous emission to the second spontaneous emission is adjusted accordingly until a continuous spectrum with wavelength in range from 750 to 1350 nm is created by a combinational overlapping effect of respective spectrum emitted by the first spontaneous emission and the second spontaneous emission in accordance with the superposition principle.

9. The method for generating ultrabroadband near-infrared light as claimed in claim 8, wherein the polarization orientation of the visible laser is regulated via adjusting the polarization orientation of the visible laser to the extent that the relative intensity for the first spontaneous emission to the second spontaneous emission is in same numerical order, so that the continuous spectrum with the full width at half maximum (FWHM) not less than 220 nm is created.

10. The method for generating ultrabroadband near-infrared light as claimed in claim 8, further comprising:
before performing the lateral-plating process, performing a Laser heated pedestal growth (LHPG) technique for the core, to reduce an original diameter of the core down to range of 5 to 200 μm.
